(19) United States
(12) Patent Application Publication
(10) Pub. No.: US 2018/0363703 A1
(43) Pub. Date: Dec. 20, 2018

(54) TURBOMACHINE CONTROL SYSTEM FOR HAZARDOUS AREAS

(71) Applicant: Nuovo Pignone Tecnologie Srl, Florence (IT)

(72) Inventors: Claudio LOTTI, Florence (IT); Daniele GIREZZI, Florence (IT); Roberto SANGIOVANNI, Florence (IT); Massimiliano ORTIZ NERI, Florence (IT)

(21) Appl. No.: 16/003,140

(22) Filed: Jun. 8, 2018

(30) Foreign Application Priority Data
Jun. 19, 2017 (IT) 102017000067928

(51) Int. Cl. F16C 32/04; F01D 25/16; F01D 21/14; H05K 5/02

(52) U.S. Cl. CPC F16C 32/048; F01D 25/16; F01D 21/14; F16C 2360/24; F05D 2240/515; F05D 2220/40; H05K 5/02

(57) ABSTRACT

A system comprising a turbomachinery provided with a casing and having a rotor mounted on a shaft supported for rotation in the casing; the shaft is associated to a plurality of active magnetic bearings adapted to support the shaft in the casing and associated to a control system through a plurality of wires wherein the control system is housed in a control system compartment external to the casing and located in proximity thereto.

### BACKGROUND

The present disclosure relates to turbomachines. Embodiments disclosed herein specifically relate to compressors, turbines, turbocompressors, motor, generators, turbogenerator, expander-generator. More specifically, the disclosure relates to improvements to motor-compressor and expander-compressor units comprising one or more magnetic bearings supporting the driving shaft, which connects the motor/expander to the compressor.

Motor-compressor units are usually comprised of one or two outer casings which house an electric motor and a compressor, connected to one another by a driving shaft. The shaft is supported by a plurality of bearings. In some integrated applications the casing is a pressure casing comprising a motor compartment, which houses the electric motor, and a compressor compartment, which houses the compressor.

Turboexpander units are commonly used machines for converting the power contained in a flow of compressed gas into useful mechanical power available on an output shaft of the turboexpander. The output shaft can be used to mechanically drive a rotating machine, for example a compressor or an electric generator. Integrated turboexpander units usually comprise a gas tight casing housing a turboexpander with a rotating wheel or a plurality of rotating wheels, provided with blades, mounted on a rotating shaft. The shaft is supported for rotation in the casing and is mechanically connected to the rotor of a compressor or an electric generator, the stator whereof is stationarily mounted in the casing.

The rotating shaft of these turbomachines is usually supported in the casing by means of a plurality of bearings. In earlier units oil lubricated bearings were used for this purpose. More recently, active magnetic bearings (hereinafter referred to also as AMBs) have been developed. AMBs avoid the need of lubricating oil and therefore overcome drawbacks related to the presence of oil in the gas flow through the unit.

AMBs are controlled by an electronic control system. The electronic control system must be connected to the magnetic bearings housed in the machine casing, therefore a cable connection electrically connects the control system with the interior of the machine casing.

The turbomachinery working with compressed gas are normally located in sites classified as hazardous due to the risk of explosion associated with the presence of flammable gas or vapour. The AMB control system is placed externally of the machine casing, in a safe area outside of the classified area, and at a variable distance therefrom up to several hundreds of meters. Junction boxes are commonly used to act as a separation element between the turbomachine and the control system. On the turbomachine side of the junction box there are the cables connected to the turbomachine, on the control side of the junction box there are the cables connected to the control system. In case of pressurized machines, the cables on the turbomachine side of the junction box pass through a protection system able to withstand the differential pressure between the turbomachine room and the external environment, while no special requirement is necessary for the cables of the control system side, apart from the necessity to increase their cross section depending on the length to avoid power loss.

The use of a relatively large number of long cables renders these known systems expensive and cumbersome. Furthermore, known systems require some on-site tuning activities due to different cable length and section between the cables employed for the factory test and set-up and the cables installed on-site. Improvements relating to the arrangement of the control system of the active magnetic bearings in a turbomachine unit would thus be desirable.

### BRIEF DESCRIPTION OF THE INVENTION

According to an exemplary embodiments, a turbomachine is described comprising a casing, a turbomachinery having a rotor mounted on a shaft coupled with a plurality of AMBs and supported for rotation in the casing. The AMBs are managed by an AMB control system connected through a plurality of cables and wires and housed in a control system compartment external to the casing and located in proximity thereto. The cables connecting the AMBs to the AMBs control system are therefore much shorter than usual and have a much smaller cross section, moreover no junction box is required with an improvement in terms of compactness, reliability and cost reduction.

Advantageously, the control system compartment comprise a cabinet that can be either pressurized, or explosion proof or both. Explosion proof cabinet allows AMB control systems which are not designed for classified hazardous areas to be employed. Pressurization of the cabinet of the control system compartment saves the electronics inside from possible contamination with the process gas of the turbomachine.

The AMBs control system can be managed from remote and therefore the operator does not need to work in the classified area where the turbomachinery and the AMBs control system are located.

If the magnetic bearings control system is designed to work in classified hazardous areas, it can be placed directly in close proximity of the turbomachine without the need of an explosion proof container.

The control system compartment can host one or more electric and electronic components. In some embodiments such components are configured and arranged to control and power the magnetic bearings which support the shaft of the turbomachinery. In some embodiments the control system is an integrated control system comprising a section for the control of the magnetic bearings and a further section for the control of the turbomachinery.

### BRIEF DESCRIPTION OF THE DRAWINGS

The exemplary embodiments described herein will become more apparent when considered in conjunction with the accompanying drawings wherein:

FIG. 1 illustrates a turbomachine—namely an expander-compressor unit—connected to an AMB control system according to the prior art;

FIG. 2 illustrates a turbomachine according to embodiments described herein;

FIG. 3 illustrates an integrated control system according to embodiments described herein;

FIG. 4 illustrates the network topology of the control system of the integrated control system depicted in FIG. 3;

FIG. 5 illustrates an AMB control system separated from the unit control system according to embodiments described herein; and

FIG. 6 illustrates the network topology of the control system depicted in FIG. 5.

### DETAILED DESCRIPTION OF THE INVENTION

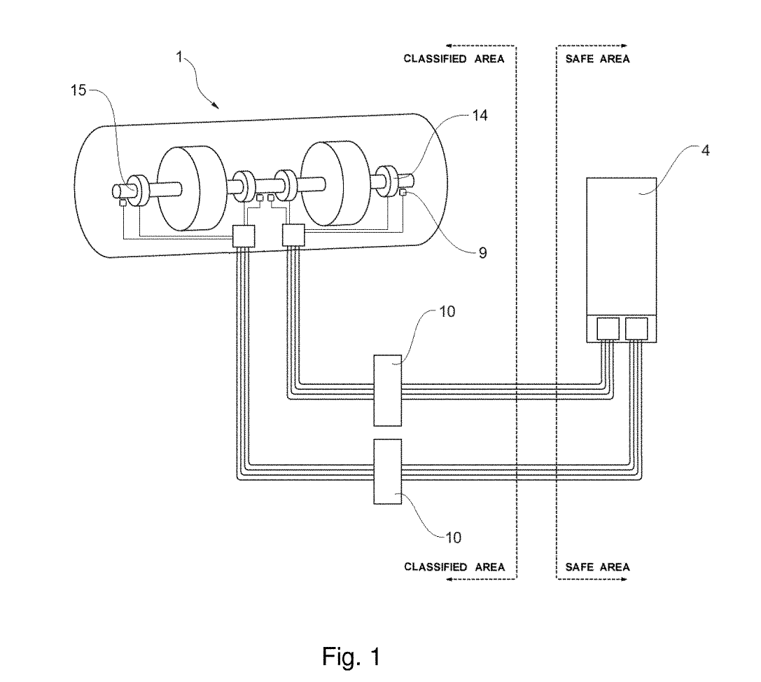

FIG. 1 shows an exemplary turbomachine 1—namely an expander-compressor unit—connected to an AMB control system according to the prior art.

As the AMB control system is located in a control system compartment 4 far away from the turbomachine, intermediate junction boxes 10 are used. These junction boxes act as separation elements between the turbomachine 1 and the AMB control system.

The junction boxes 10, one for the power cables and one for the signal cables, are installed in the classified area where the turbomachine is installed, not far from the turbomachine. Typically the junction boxes 10 can be installed on the skid supporting the turbomachine or in its vicinity, while the AMB control system is installed in a control system compartment 4 located in a safe area at a distance which can measure up to several hundreds of meters and is typically in the range 100 m to 700 m.

The cable size from junction boxes 10 to AMB control system depends on the distance between the field and the control system compartment 4. Longer the distance, larger is the required power cable cross section to reduce power loss.

On the turbomachine side, in typical applications, power cables and signal cables have, respectively, less than 10 mm² and 1 mm² cross section due to short distance. Larger cross sections are obviously possible.

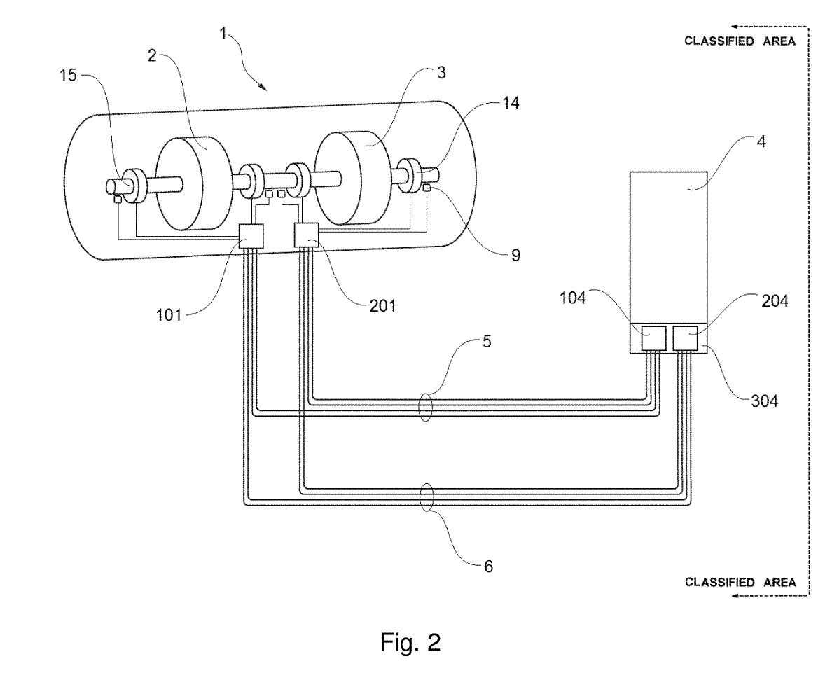

FIG. 2 exemplary shows a turbomachine according to embodiments herein. The turbomachine 1 comprises a casing, an expander 2 having a rotor mounted on a shaft 15 supported for rotation in the casing, a compressor 3 arranged in the casing and comprised of a rotor mounted on the shaft for co-rotation with the turbo-expander rotor.

The shaft 15 is supported in the casing by means of a plurality of bearings. In some embodiments a first radial bearing can be arranged at a first end of shaft 15. A second radial bearing can be provided at a second end of the shaft 15. In some embodiments one or more axial bearings can further be provided. A different number of magnetic bearings can be foreseen, e.g. depending upon design choices and/or requirements of the expander-compressor unit. More variability in the number of bearings, and thus of the cables, can be found in motor-compressor units which are part of the present disclosure.

One, some or all said bearings can be magnetic bearings and more specifically AMBs 14. AMBs 14 are known to those skilled in the art and will not be described in greater detail herein.

AMBs 14 require an electronic control system 7, which provides power and control signals to the magnetic bearings. According to embodiments disclosed herein the AMB control system 7 is housed in a control system compartment 4 external to the casing and located in proximity thereto. In some embodiments, the control system compartment 4 is pressurized to guarantee that the electronics inside is safe from possible contamination with the process gas of the turbomachine. In an embodiment the control system compartment 4 is located at a distance typically not greater than 20 m from the casing of the turbomachine 1.

The control system compartment 4 may house only the AMB control system 7 or an integrated control system comprising the AMB control system 7 and the turbomachinery unit control system 8 (UCS).

A turbomachinery control system 8 is based on PLC hardware and typically comprises a main controller 108 and a safety controller 208. The main controller 108 implements the machine start/stop sequence inclusive of all auxiliaries, antisurge control, performance control and load sharing control, while the safety controller 208 implements trip logics and other safety functions.

The unit control system 8 is generally hosted in a control cabinet with front door opening located in a safe area far away from the turbomachine. The operator interface is usually a PC with touchscreen panel located in the cabinet (HMI 121) or remotely connected (DCS 122) through a firewall 123 preferably provided with redundant connection.

In existing systems, the unit control system and the AMB control system 7 are independent and located in a safe area.

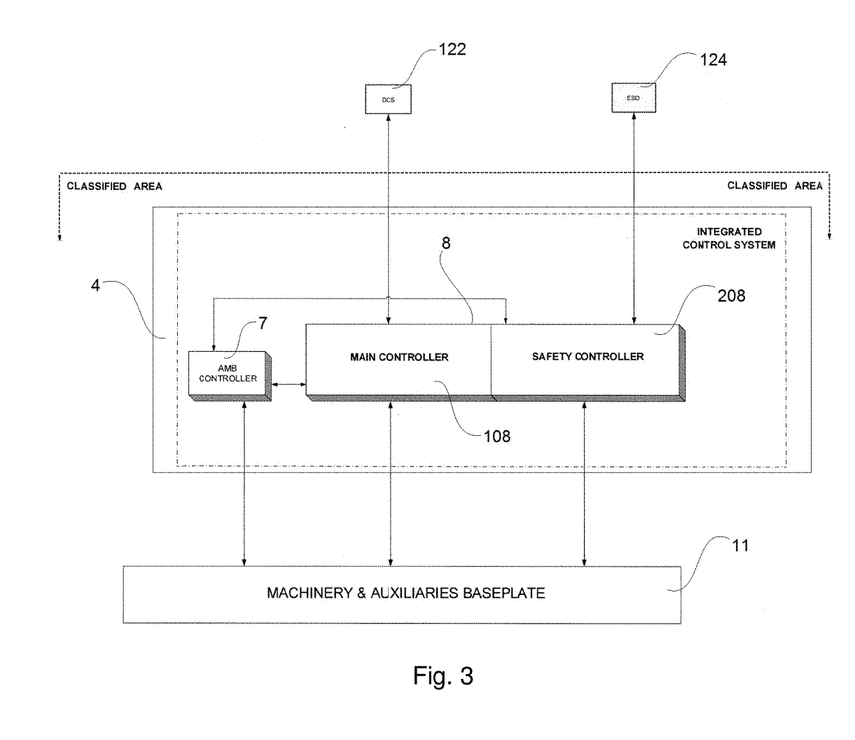

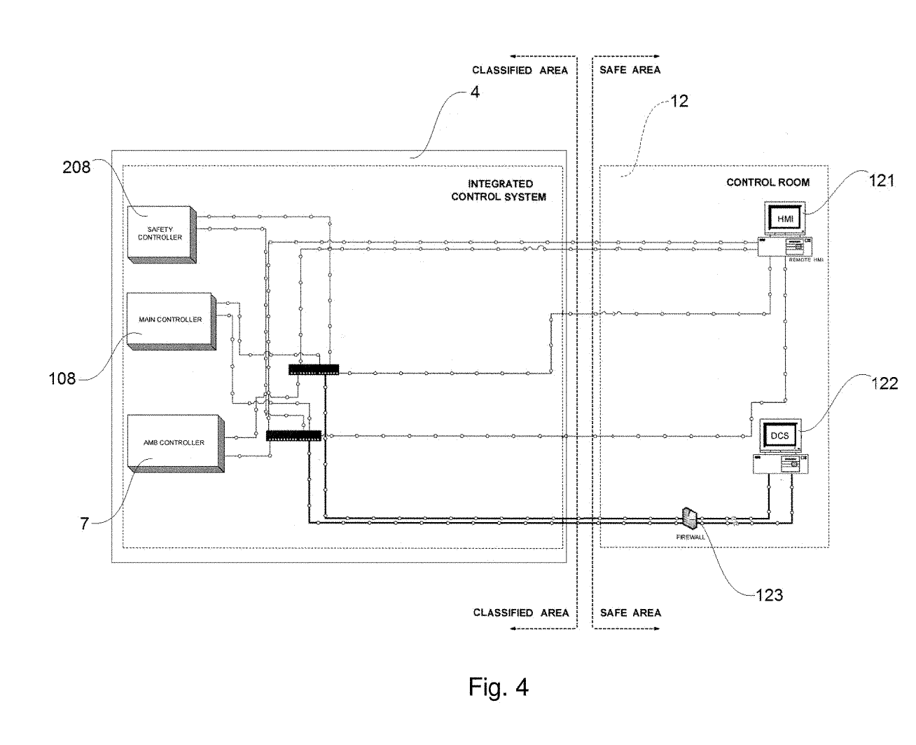

FIG. 3 shows an integrated control system according to embodiments herein. In this configuration, the AMB control system 7, the main controller 108 and the safety controller 208 are all hosted in a control system compartment 4 comprising an explosion proof cabinet and located in a classified hazardous area close to the machinery & auxiliary baseplate 11, while the user interface 121 (HMI) is positioned in a remote control room 12 located in a safe area as best shown in FIG. 4.

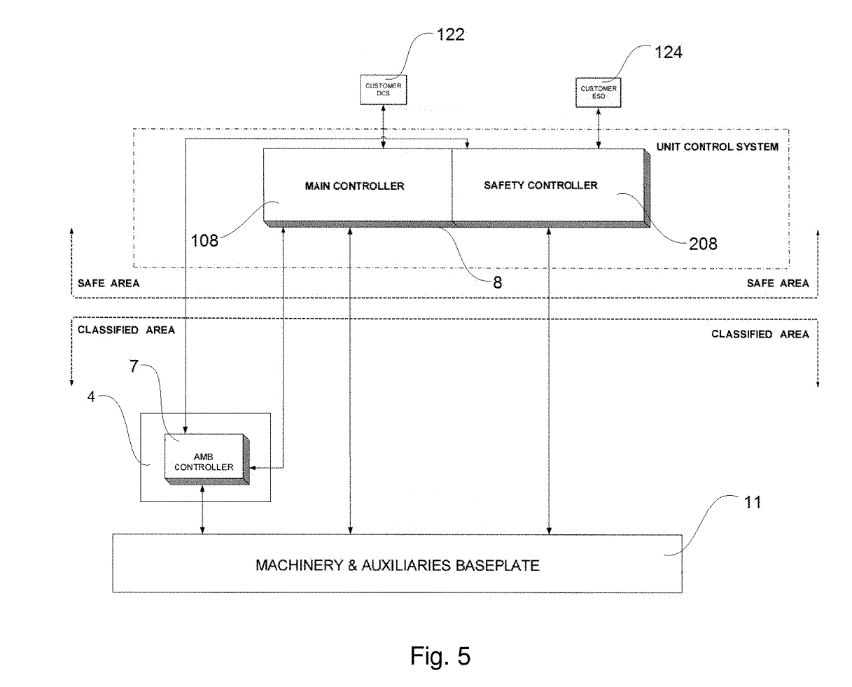

FIG. 5 shows a control system according to a further embodiment wherein the AMB control system 7 and the unit control system 8 are separate units. Like in existing systems, the main controller 108 and the safety controller 208 are located in a safe area 13 remote from the turbomachinery 2.

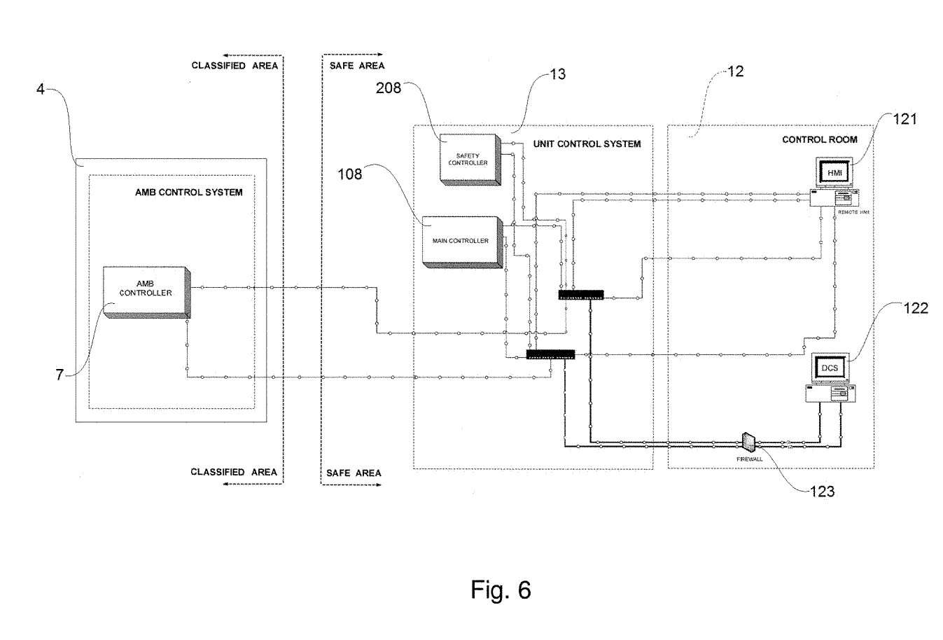

The user interface 121 (HMI) can be positioned in the unit control system area 13 or in a dedicated control room 12 in safe area connected to the unit control system 8 while the AMB control system 7 is installed in a control system compartment 4 comprising an explosion proof cabinet and located in hazardous area close to the machinery & auxiliary baseplate 11 as best shown in FIG. 6.

Remotely connected user interface 122 (DCS) through a firewall 123 preferably provided with redundant connection can be employed like in existing systems as well as emergency shut down system 124 (ESD) interfaced with the unit control system 8.

Since the electric and electronic components can be affected by the processed gas of the turbomachine, the control system compartment 4 is preferably pressurized and filled with air or an inert gas, for instance nitrogen. In the context of the present description and attached claims, the term inert gas also encompasses noble gases, such as helium, for instance, as well as gas mixtures, for instances mixtures mainly composed of nitrogen or helium.

In some embodiments, the control system compartment 4 comprises a pressurized cabinet, for example an ATEX cabinet according to European Directive 2014/34/EU.

In some embodiments a connector flange can be provided on the casing of the turbomachine and on the control system compartment 4 for the passage of cables 5, 6 which connect the expander-compressor unit 1 to the control system compartment 4. Suitable passages, channels or protective sheaths 304 can in practice be used to protect and contain the wiring in order to prevent damages during assembling of the components of the expander-compressor unit and/or during operation thereof. In some embodiments, the cables pass through a protection system connecting the casing to the control system compartment 4.

Electric connection between the electronic components of the control system compartment and the magnetic bearings can be obtained, for example, by means of pairs of electric connectors 101-204, 201-104 arranged on a surface of the casing and on a surface of the cabinet of the control system compartment 4.

In some embodiments, the control system compartment 4 comprises an explosion proof cabinet, for example an ATEX cabinet according to European Directive 2014/34/EU.

The cables connecting the control system compartment 4 with the casing of the turbomachine 1 typically comprise power cables 5 and signal cables 6. The power cables 5 connect the control system compartment 4 with the coils of the active magnetic bearings to control the current flowing thereto, while the signal cables 6 connect the control system with sensors 9 located in the casing. Such sensors may, for example, comprise position sensors, radial and/or axial, to monitor the position of the rotor, temperature sensors, vibration sensors, shaft speed sensors, accelerometers.

In an embodiment each active magnetic bearing comprises at least two coils, typically four coils per radial bearing, two coils per axial bearing, each driven by a couple of power cables.

Embodiments have been mainly illustrated with reference to an expander-compressor unit, but the teaching of the present disclosure can be used for any type of turbomachine having magnetic bearing, such as, for example, expander-generator, motor-compressor, motor, generator, turbo-generator units.

The description of exemplary embodiments refer to the accompanying drawings. The same reference numbers in different drawings identify the same or similar elements. The following detailed description does not limit the invention. Instead, the scope of the invention is defined by the appended claims.

Reference throughout the specification to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

What we claim is:

1. A turbomachine comprising:
a casing;
a turbomachinery having a rotor mounted on a shaft supported for rotation in the casing;
a plurality of active magnetic bearings configured and arranged for supporting the shaft in the casing;
an active magnetic bearing control system for controlling the magnetic bearings through a plurality of cables;
wherein the active magnetic bearing control system is housed in a control system compartment external to the casing and located in proximity thereto.

2. Turbomachine according to claim 1, wherein the control system compartment is pressurized.

3. Turbomachine according to claim 2, wherein the control system compartment is pressurized with air or with an inert gas.

4. Turbomachine according to claim 3, wherein the inert gas is chosen in the group comprising nitrogen, helium and gas mixtures mainly composed of nitrogen or helium.

5. Turbomachine according to claim 1, wherein the control system compartment comprises an explosion proof cabinet.

6. Turbomachine according to claim 1, wherein the control system compartment comprises a cabinet compliant with the European Union Directive 2014/34/EU.

7. Turbomachine according to claim 1, wherein the cables comprise power cables and signal cables, the power cables connecting the control system with the coils of the magnetic bearings to control the current flowing thereto, the signal cables connecting the control system with sensors in the casing, such sensors comprising position sensors to monitor the position of the rotor.

8. Turbomachine according to claim 7, wherein the power cables are at least two for each coil, each magnetic bearing comprising at least two coils, typically four coils per radial bearing, two coils per axial bearing.

9. Turbomachine according to claim 7, wherein the signal cables are two, four or eight cables for each sensor, the sensors comprising one or more sensors selected from the group comprising: axial position sensors, radial position sensors, shaft speed sensors, vibration sensors, temperature sensors.

10. Turbomachine according to claim 1, wherein the cables pass through a protection system connecting the casing to the control system compartment.

11. Turbomachine according to claim 1, wherein the turbomachinery comprises:
a turboexpander or motor having a rotor mounted on a shaft supported for rotation in the casing;
a compressor arranged in the casing and comprised of a rotor mounted on the shaft for co-rotation with turboexpander/motor rotor.

12. Turbomachine according to claim 1, comprising a unit control system for the control of the turbomachinery, wherein the magnetic bearing control system and the unit control system are hosted in the control system compartment.

13. Turbomachine according to claim 12, further comprising a user interface connected with the unit control system and positioned in a remote control room located in a safe area far away from the turbomachinery.

14. Turbomachine according to claim 12, wherein the magnetic bearing control system and the unit control system are separate units, the unit control system being located in a safe area remote from the machinery while the magnetic bearing control system is located in the control system compartment exploiting explosion protection in hazardous area close to the machinery.

15. Turbomachine according to claim 14, wherein the user interface is located in the same safe area hosting the unit control system.

16. Turbomachine according to claim 12, wherein the unit control system comprises a main controller and a safety controller, the main controller implementing main controls of the machinery chosen in the group comprising start/stop sequence inclusive of auxiliaries, antisurge control, performance control, load sharing control, while the safety controller performs safety functions like trip logics.
